(19) United States
(12) Patent Application Publication
(10) Pub. No.: US 2025/0160045 A1
(43) Pub. Date: May 15, 2025

(54) OPTICAL DETECTOR

(71) Applicant: QuantumZ Inc., KAOHSIUNG CITY (TW)

(72) Inventors: CHUNG-YU HONG, KAOHSIUNG CITY (TW); CHUN-CHIEH CHEN, KAOHSIUNG CITY (TW); CHUN-I WU, KAOHSIUNG CITY (TW); LONG-YI LIN, KAOHSIUNG CITY (TW); MING-CHE HSIEH, KAOHSIUNG CITY (TW)

(21) Appl. No.: 18/899,905

(22) Filed: Sep. 27, 2024

(30) Foreign Application Priority Data
Nov. 10, 2023 (TW) 112143340

(51) Int. Cl. H01L 31/0304; H01L 31/0232

(52) U.S. Cl. CPC H10F 77/1248; H10F 77/413

(57) ABSTRACT

An optical detector is provided, including: a substrate, a first cladding layer, a second cladding layer, an absorber, a first contact layer, a second contact layer, a buffer layer, a first metal material, and a second metal material. The substrate defines a thickness direction and has a light incident side. The first cladding layer is disposed on a side of the substrate opposite to the light incident side, and the absorber is disposed between the first cladding layer and the second cladding layer. The first contact layer is disposed between the substrate and the first cladding layer. The buffer layer is disposed on a side of the first contact layer and includes a plurality of individual layers, and lattice mismatches with gallium arsenide of the plurality of individual layers are progressively increased in the thickness direction toward a side remote from the substrate.

### BACKGROUND OF THE INVENTION

### Field of the Invention

The present invention relates to an optical detector.

### Description of the Prior Art

A conventional optical detector for semiconductor includes a substrate made of gallium arsenide, a n-cladding layer, an active region and a p-cladding layer which are sequentially stacked on a side of the substrate, and a light incident surface of the optical detector is located at a side of the optical detector close to the p-cladding layer. However, the conventional optical detector has problems of small capacitance, small area of the active region, and poor coupling efficiency, which results in poor optical signal reception. In addition, the lattice matching between the n-cladding layer and the substrate is insufficient, which may generate internal stress and affect the performance of the optical detector, and is not conducive to the growth of said layers during manufacturing.

The present invention is, therefore, arisen to obviate or at least mitigate the above-mentioned disadvantages.

### SUMMARY OF THE INVENTION

The main object of the present invention is to provide an optical detector, which has good optical coupling efficiency and response.

To achieve the above and other objects, the present invention provides an optical detector, including: a substrate, a first cladding layer, a second cladding layer, an absorber, a first contact layer, a second contact layer, a buffer layer, a first metal material and a second metal material. The substrate defines a thickness direction and has a light incident side. The first cladding layer is disposed on a side of the substrate opposite to the light incident side in the thickness direction. The second cladding layer is disposed on a side of the first cladding layer opposite to the substrate in the thickness direction. The absorber is disposed between the first cladding layer and the second cladding layer. The first contact layer is disposed between the substrate and the first cladding layer. The second contact layer is disposed on a side of the second cladding layer opposite to the absorber. The buffer layer is disposed on a side of the first contact layer and includes a plurality of individual layers overlapped with one another in the thickness direction, and lattice mismatches with gallium arsenide of the plurality of individual layers are progressively increased in the thickness direction toward a side remote from the substrate. The first metal material is electrically connected with the first contact layer, and the second metal material is electrically connected with the second contact layer.

The present invention will become more obvious from the following description when taken in connection with the accompanying drawings, which show, for purpose of illustrations only, the preferred embodiment(s) in accordance with the present invention.

### BRIEF DESCRIPTION OF THE DRAWINGS

FIG. 1 is a cross-sectional diagram of a first preferable embodiment of the present invention;

FIG. 2 is a cross-sectional diagram of a second preferable embodiment of the present invention; and

FIG. 3 is a cross-sectional diagram of a third preferable embodiment of the present invention.

### DETAILED DESCRIPTION OF THE PREFERRED EMBODIMENTS

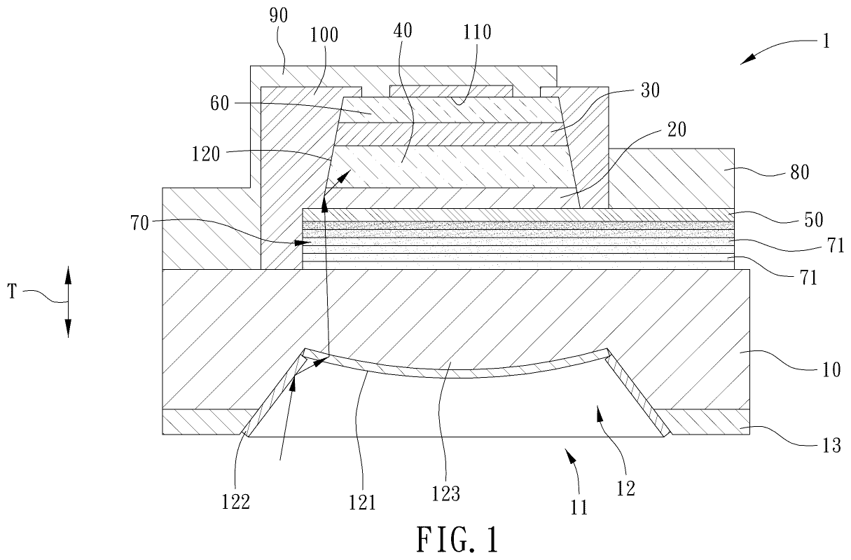

Please refer to FIG. 1 for a first preferable embodiment of the present invention. An optical detector 1 of the present invention includes a substrate 10, a first cladding layer 20, a second cladding layer 30, an absorber 40, a first contact layer 50, a second contact layer 60, a buffer layer 70, a first metal material 80 and a second metal material 90.

The substrate 10 defines a thickness direction T and has a light incident side 11. The first cladding layer 20 is disposed on a side of the substrate 10 opposite to the light incident side 11 in the thickness direction T. The second cladding layer 30 is disposed on a side of the first cladding layer 20 opposite to the substrate 10 in the thickness direction T. The absorber 40 is disposed between the first cladding layer 20 and the second cladding layer 30. The first contact layer 50 is disposed between the substrate 10 and the first cladding layer 20. The second contact layer 60 is disposed on a side of the second cladding layer 30 opposite to the absorber 40. The buffer layer 70 is disposed on a side of the first contact layer 50 and includes a plurality of individual layers 71 overlapped with one another in the thickness direction T, and lattice mismatches with gallium arsenide of the plurality of individual layers 71 are progressively increased in the thickness direction T toward a side remote from the substrate 10. The first metal material 80 is electrically connected with the first contact layer 50, and the second metal material 90 is electrically connected with the second contact layer 60. Therefore, the optical detector 1 is a back-illuminated photo detector, and there are appropriate lattice matches between the buffer layer 70, the substrate 10 and the first cladding layer 20, which contributes to receiving high-speed optical signal and good optical coupling efficiency and response.

In this embodiment, the buffer layer 70 is located between the first contact layer 50 and the substrate 10, and the first contact layer 50 is made of a material having a lattice mismatch greater than 0.5% with gallium arsenide. The lattice mismatches with gallium arsenide of the plurality of individual layers 71 are progressively increased to be greater than 0.5% in a direction from the substrate 10 toward the first contact layer 50 so as to provide a progressive change of the band gap between the substrate 10 and the first contact layer 50, which avoids structural instability and performance loss due to inappropriate lattice mismatches between said layers. Specifically, the substrate 10 is made of a material including gallium arsenide (GaAs), a thickness of the substrate 10 is between 50 μm and 300 μm, and the material of the substrate 10 may be semi-insulating or be doped with a p-type or n-type dopant. The first contact layer 50 may be made of a material including at least one of GaAs, aluminum gallium arsenide (AlGaAs), gallium indium arsenide (GaInAs), aluminum gallium indium arsenide (AlGaInAs), gallium indium phosphide (GaInP) and aluminum gallium indium phosphide (AlGaInP). The material of the first contact layer 50 may be heavily doped with a p-type or n-type dopant, and a doping concentration of the material of the first contact layer 50 is between 3.0×10¹⁸ cm⁻³ and 2.0×10²⁰ cm⁻³. The buffer layer 70 is made of a material including at least one of GaAs, AlGaAs, GaInAs, AlGaInAs, GaInP and AlGaInP. The material of the buffer layer 70 may be doped with a p-type or n-type dopant, and a doping concentration of the material of the buffer layer 70 is between 1.0×10¹⁷ cm⁻³ and 2.0×10¹⁹ cm⁻³.

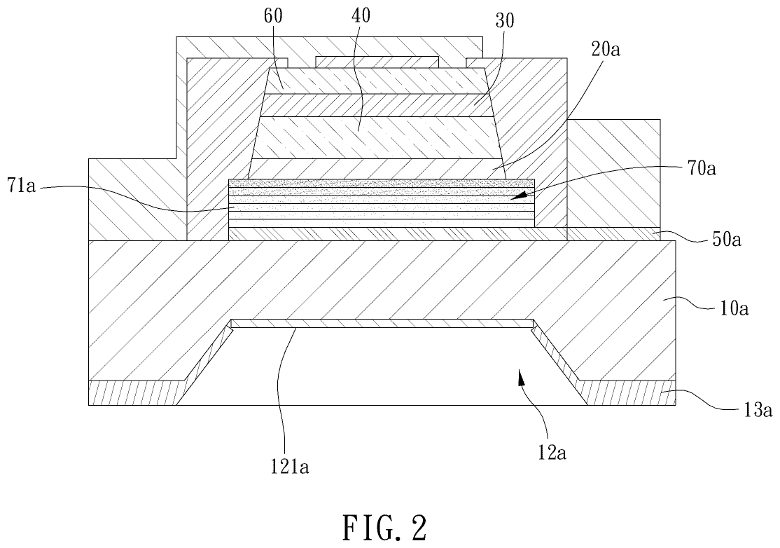

In other embodiments, the buffer layer 70a may be located between the first cladding layer 20a and the first contact layer 50a, and the first contact layer 50a is made of a material having a lattice mismatch less than 0.5% with gallium arsenide. The first cladding layer 20a is made of a material having a lattice mismatch greater than 0.5% with gallium arsenide, and the lattice mismatches with gallium arsenide of the plurality of individual layers 71a are progressively increased to be greater than 0.5% in a direction from the first contact layer 50a toward the first cladding layer 20a, as shown in FIG. 2. The material and the position of the buffer layer 70a is adjustable according to the lattice mismatch of the first contact layer 50a with gallium arsenide.

Specifically, the optical detector 1 is configured to receive an optical signal with a wavelength between 900 nm and 1200 nm, and a band gap of the absorber 40 is lower than a photon energy of the optical signal. Band gaps of the first cladding layer 20, the second cladding layer 30, the first contact layer 50, the second contact layer 60, the buffer layer 70 and the substrate 10 are higher than the photon energy of the optical signal, which effectively prevents the optical signal from being absorbed by other layers than the absorber 40 for less optical loss. For example, the absorber 40 may be made of a material including at least one of GaAs, AlGaAs, GaInAs, AlGaInAs, GaInP and AlGaInP. The material of the absorber 40 has a lattice mismatch greater than 0.5% with gallium arsenide and may be doped with a p-type or n-type dopant or be undoped, and a doping concentration of the material of the absorber 40 is smaller than 1.0×10¹⁶ cm⁻³. The first cladding layer 20 and the second cladding layer 30 are respectively made of a material including at least one of GaAs, AlGaAs, GaInAs, AlGaInAs, GaInP and AlGaInP. The materials of the first cladding layer 20 and the second cladding layer 30 respectively have a lattice mismatch greater than 0.5% with gallium arsenide and may be doped with a p-type or n-type dopant, and doping concentrations of the materials of the first cladding layer 20 and the second cladding layer 30 are respectively between 1.0×10¹⁷ cm⁻³ and 2.0×10¹⁹ cm⁻³.

The optical detector 1 further includes a dielectric layer 100 disposed between the second contact layer 60 and the second metal material 90, and the dielectric layer 100 is made of a material including at least one of silicon oxide, silicon nitride, aluminum oxide, titanium oxide, magnesium fluoride, tantalum oxide and indium tin oxide. The dielectric layer 100 includes a first reflective surface 110 facing toward the second contact layer 60 so as to reflect the optical signal toward the absorber 40 to increase optical receiving efficiency. A thickness of the dielectric layer 100 is between 10 nm and 1000 nm to provide good reflection effect. In this embodiment, the dielectric layer 100 further includes a second reflective surface 120, and the second reflective surface 120 extends and is covered on outer circumferential surfaces of the first cladding layer 20, the absorber 40 and the second cladding layer 30. The second reflective surface 120 extends obliquely and radially inward from the first cladding layer 20 toward the second cladding layer 30, which is help to reflect the optical signal toward a central region of the optical detector 1 and increase optical receiving efficiency. In other embodiments, the second reflective surface may extend in a direction parallel to the thickness direction.

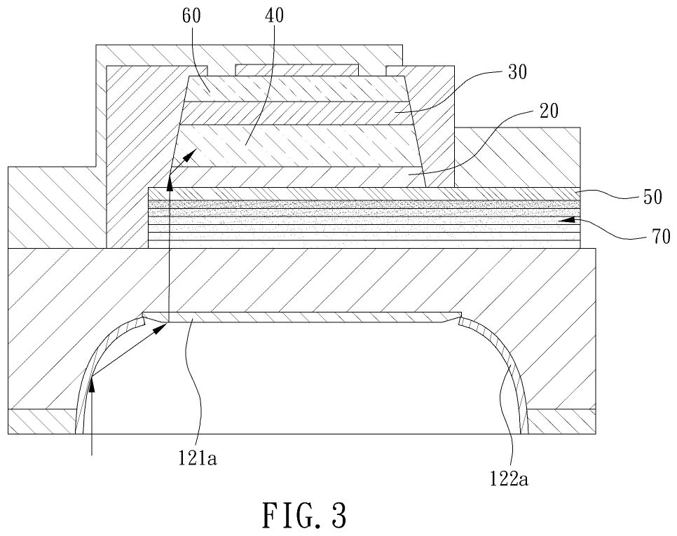

Moreover, the light incident side 11 of the substrate 10 has a recessed portion 12, and the recessed portion 12 includes a light incident surface 121 and a light guiding surface 122 extending around the light incident surface 121. The light incident surface 121 is an anti-reflective surface, and the light guiding surface 122 is a high-reflective surface. In this embodiment, the light incident surface 121 is formed of an anti-reflective coating or film, and the light guiding surface 122 is formed of a total reflective coating or film. The light guiding surface 122 is an inclined surface inclined between 45° and 80° relative to the thickness direction T, and a depth of the recessed portion 12 is preferably lager than or equal to ½ of a thickness of the substrate 10 so that an incident light is reflected toward the light incident surface 121, as shown by arrows in FIG. 1, which has good optical coupling effect and reduces optical loss. In addition, the recessed portion 12 prevents the light incident surface 121 from abrasion during assembling. Preferably, the recessed portion 12 further includes a convex lens 123, the convex lens 123 may be integrally formed with the substrate 10 or additionally attached to the substrate 10, and the light incident surface 121 is formed on the convex lens 123, which is help to collect the optical signal. In other embodiments, the substrate 10a may have no convex lens disposed thereon, as shown in FIG. 2; the light guiding surface 122a may be an arcuate concave surface, as shown in FIG. 3, which also provides good light guiding effect.

The light incident side 11 of the substrate 10 further has a light absorbing layer 13 extending around the light guiding surface 122, and the light absorbing layer 13 is made of a material including at least one of chromium, iron, manganese, platinum, titanium, tungsten, silicon oxide (SiOx), aluminum oxide (AlOx), hafnium oxide (HfOx) and titanium oxide (TiOx). Therefore, the light absorbing layer 13 can absorb stray light so that the optical detector 1 provides better response. In other embodiments, the recessed portion 12a may be configured without the light guiding surface, and the light absorbing layer 13a may be at least partially located with the recessed portion 12a and extends around the light incident surface 121a, as shown in FIG. 2, which is also help to absorb stray light.

Although particular embodiments of the invention have been described in detail for purposes of illustration, various modifications and enhancements may be made without departing from the spirit and scope of the invention. Accordingly, the invention is not to be limited except as by the appended claims.

What is claimed is:

1. An optical detector, including:
a substrate, defining a thickness direction, having a light incident side;
a first cladding layer, disposed on a side of the substrate opposite to the light incident side in the thickness direction;
a second cladding layer, disposed on a side of the first cladding layer opposite to the substrate in the thickness direction;
an absorber, disposed between the first cladding layer and the second cladding layer;
a first contact layer, disposed between the substrate and the first cladding layer;
a second contact layer, disposed on a side of the second cladding layer opposite to the absorber;
a buffer layer, disposed on a side of the first contact layer, including a plurality of individual layers overlapped with one another in the thickness direction, lattice mismatches with gallium arsenide of the plurality of individual layers progressively increased in the thickness direction toward a side remote from the substrate;
a first metal material, electrically connected with the first contact layer; and
a second metal material, electrically connected with the second contact layer.

2. The optical detector of claim 1, wherein the buffer layer is located between the first contact layer and the substrate, the first contact layer is made of a material with a lattice mismatch greater than 0.5% with gallium arsenide, and the lattice mismatches with gallium arsenide of the plurality of individual layers are progressively increased to be greater than 0.5% in a direction from the substrate toward the first contact layer.

3. The optical detector of claim 1, wherein the buffer layer is located between the first cladding layer and the first contact layer, the first contact layer is made of a material having a lattice mismatch less than 0.5% with gallium arsenide, the first cladding layer is made of a material having a lattice mismatch greater than 0.5% with gallium arsenide, and the lattice mismatches with gallium arsenide of the plurality of individual layers are progressively increased to be greater than 0.5% in a direction from the first contact layer toward the first cladding layer.

4. The optical detector of claim 1, further including a dielectric layer disposed between the second contact layer and the second metal material, wherein the dielectric layer is made of a material including at least one of silicon oxide, silicon nitride, aluminum oxide, titanium oxide, magnesium fluoride, tantalum oxide and indium tin oxide, and the dielectric layer includes a first reflective surface facing toward the second contact layer.

5. The optical detector of claim 4, wherein a thickness of the dielectric layer is between 10 nm and 1000 nm.

6. The optical detector of claim 4, wherein the dielectric layer further includes a second reflective surface, the second reflective surface extends and is covered on outer circumferential surfaces of the first cladding layer, the absorber and the second cladding layer, and the second reflective surface extends obliquely and radially inward from the first cladding layer toward the second cladding layer.

7. The optical detector of claim 1, wherein the light incident side of the substrate has a recessed portion, the recessed portion includes a light incident surface and a light guiding surface extending around the light incident surface, the light incident surface is an anti-reflective surface, and the light guiding surface is a high-reflective surface.

8. The optical detector of claim 7, wherein the light guiding surface is an inclined surface inclined between 45° and 80° relative to the thickness direction.

9. The optical detector of claim 7, wherein the light guiding surface is an arcuate concave surface.

10. The optical detector of claim 7, wherein the recessed portion further includes a convex lens, and the light incident surface is formed on the convex lens.

11. The optical detector of claim 7, wherein the light incident side of the substrate further has a light absorbing layer extending around the light guiding surface, and the light absorbing layer is made of a material including at least one of chromium, iron, manganese, platinum, titanium, tungsten, silicon oxide, aluminum oxide, hafnium oxide and titanium oxide.

12. The optical detector of claim 1, wherein the light incident side of the substrate has a recessed portion and a light absorbing layer, the recessed portion includes a light incident surface, the light absorbing layer is at least partially located with the recessed portion and extends around the light incident surface, and the light absorbing layer is made of a material including at least one of chromium, iron, manganese, platinum, titanium, tungsten, silicon oxide, aluminum oxide, hafnium oxide and titanium oxide.

13. The optical detector of claim 1, wherein the substrate is made of a material including gallium arsenide (GaAs), and a thickness of the substrate is between 50 μm and 300 μm.

14. The optical detector of claim 1, wherein the buffer layer is made of a material including at least one of gallium arsenide (GaAs), aluminum gallium arsenide (AlGaAs), gallium indium arsenide (GaInAs), aluminum gallium indium arsenide (AlGaInAs), gallium indium phosphide (GaInP) and aluminum gallium indium phosphide (AlGaInP).

15. The optical detector of claim 1, wherein the optical detector is configured to receive an optical signal with a wavelength between 900 nm and 1200 nm, a band gap of the absorber is lower than a photon energy of the optical signal, and band gaps of the first cladding layer, the second cladding layer, the first contact layer, the second contact layer, the buffer layer and the substrate are higher than the photon energy of the optical signal.
